(19) United States
(12) Patent Application Publication
(10) Pub. No.: US 2019/0324160 A1
(43) Pub. Date: Oct. 24, 2019

(54) X-RAY DETECTOR AND X-RAY MEASUREMENT DEVICE USING THE SAME

(71) Applicant: HITACHI, LTD., Tokyo (JP)

(72) Inventors: Kazuyuki HOZAWA, Tokyo (JP); Takashi TAKAHAMA, Tokyo (JP)

(73) Assignee: HITACHI, LTD., Tokyo (JP)

(21) Appl. No.: 16/197,444

(22) Filed: Nov. 21, 2018

(30) Foreign Application Priority Data
Apr. 23, 2018 (JP) 2018-082253

(51) Int. Cl. G01T 1/29; H01L 27/146

(52) U.S. Cl. CPC G01T 1/2928; H01L 27/14636; H01L 27/14634

(57) ABSTRACT

An X-ray detector and an X-ray measurement device capable of improving detection efficiency of an X-ray while maintaining high resolution are provided. An X-ray detector includes: a first SDD chip that detects a fluorescent X-ray generated from a sample with a first energy sensitivity; a second SDD chip that detects the fluorescent X-ray with a second energy sensitivity different from the first energy sensitivity; a first signal line electrically connected to the first SDD chip; and a second signal line electrically connected to the second SDD chip. The X-ray detector further includes an amplifier that is electrically connected to the first signal line and the second signal line and amplifies a signal.

### TECHNICAL FIELD

The present invention relates to an X-ray detector and an X-ray measurement device using the same.

### BACKGROUND ART

An XRF (X-Ray Fluorescence analyzer, fluorescent X-ray detector) is a device not only capable of performing qualitative and quantitative analysis of a substance, but also capable of evaluating a thickness, a laminated state, and the like of the substance by irradiating the substance with an X-ray and detecting a fluorescent X-ray generated from the substance. Currently, as improvement of an X-ray detector progresses, a fluorescent X-ray detector small enough to use on a desk and having high sensitivity has been popularized. A semiconductor detector (Silicon Drift Detector: SDD) which detects the X-ray contributed to miniaturization of the XRF. The largest characteristic of the SDD is that the SDD does not only have high detection sensitivity and a small size, but also does not require a large cooling device. In the X-ray detector, it is desirable that the detection sensitivity is high in a wide energy band ranging from low energy to high energy.

In JP-A-2014-21000 (PTL 1), disclosed is a radioactive ray detector of a structure in which a signal line connects a substrate, a radioactive ray detection element, and a preamplifier through a through hole provided on the substrate such as a wiring substrate, and the like.

### CITATION LIST

### Patent Literature

PTL 1: JP-A-2014-21000

### SUMMARY OF INVENTION

### Technical Problem

In the above-mentioned X-ray detector, detection efficiency deteriorates as an X-ray becomes high energy, depending on a thickness of a Si substrate forming the X-ray detector. In an SDD manufactured with a Si substrate having a standard thickness of 0.5 mm, when incident energy exceeds 10 keV, the detection efficiency dramatically deteriorates. For this reason, there exists a method of increasing the thickness of the Si substrate as away of improving the detection efficiency of the X-ray having X-ray energy equal to or greater than 10 keV.

However, to manufacture the SDD with the thick Si substrate, there exist problems such as demand of developing and purchasing a dedicated device, decrease of a window region having high detection efficiency as the Si substrate becomes thicker, and demand of a separate high-voltage circuit. On the other hand, there exists a method of making a multi-detector by arranging or laminating a plurality of SDDs without changing the substrate thickness of the SDD. However, as the number of SDDs increases, there exist problems that an occupancy area and a volume of the X-ray detector are increased, and the cost is also increased by the increased number of amplifiers and circuits.

Patent Literature 1 does not particularly describe the energy sensitivity of radioactive ray detected by the radioactive ray detection element.

An object of the present invention is to provide a technology capable of improving the detection efficiency of the X-ray while maintaining high resolution.

The object and new features of the present invention will become apparent from descriptions of this specification and the accompany drawings thereof.

### Solution to Problem

Among the embodiments disclosed in this application, an outline of the representative embodiment will be briefly described as follows.

A representative X-ray detector includes a first semiconductor chip that detects an X-ray generated from a sample with a first energy sensitivity, and a second semiconductor chip that detects the X-ray with a second energy sensitivity different from the first energy sensitivity. The representative X-ray detector further includes a first signal line electrically connected to the first semiconductor chip, a second signal line electrically connected to the second semiconductor chip, and an amplifier that is electrically connected to the first signal line and the second signal line and amplifies a signal.

A representative X-ray measurement device includes a stage that holds a sample, an X-ray generation source that irradiates an X-ray on the sample, an X-ray detector that detects an X-ray generated from the sample, and a first processing part that edits a signal transmitted from the X-ray detector. Here, the X-ray detector includes a first semiconductor chip that detects the X-ray generated from the sample with a first energy sensitivity, and a second semiconductor chip that detects the X-ray generated from the sample with a second energy sensitivity different from the first energy sensitivity. The X-ray detector further includes a first signal line electrically connected to the first semiconductor chip, a second signal line electrically connected to the second semiconductor chip, and an amplifier that is electrically connected to the first signal line and the second signal line and amplifies a signal.

### Advantageous Effects of Invention

Among the inventions disclosed in this application, effects acquired by the representative invention will be briefly described as follows.

An X-ray detector and an X-ray measurement device including the X-ray detector are capable of improving detection efficiency of an X-ray while maintaining high resolution. It is possible to improve the detection efficiency of the X-ray by preventing an increase in cost without increasing an occupancy area and a volume of the X-ray detector.

### BRIEF DESCRIPTION OF DRAWINGS

FIG. 1 is a schematic diagram illustrating an example of a configuration of an X-ray detector according to an embodiment of the present invention.

FIG. 2 is a schematic diagram illustrating a broken part of a structure of an SDD chip used in the X-ray detector illustrated in FIG. 1.

FIG. 3 is a rear diagram illustrating an example of a structure of a first SDD chip used in the X-ray detector illustrated in FIG. 1.

FIG. 4 is a rear diagram illustrating an example of a structure of a second SDD chip used in the X-ray detector illustrated in FIG. 1.

FIG. 5 is a cross sectional diagram illustrating an example of a laminated structure of the first SDD chip and the second SDD chip used in the X-ray detector illustrated in FIG. 1, taken along the line A-A in FIGS. 3 and 4.

FIG. 6 is a rear diagram illustrating a structure of a first modified example of the second SDD chip used in the X-ray detector illustrated in FIG. 1.

FIG. 7 is a cross sectional diagram illustrating a first modified example of the laminated structure of the first SDD chip and the second SDD chip used in the X-ray detector illustrated in FIG. 1, taken along the line B-B in FIGS. 3 and 6.

FIG. 8 is a rear diagram illustrating a structure of a second modified example of the second SDD chip used in the X-ray detector illustrated in FIG. 1.

FIG. 9 is a cross sectional diagram illustrating a second modified example of the laminated structure of the first SDD chip and the second SDD chip used in the X-ray detector illustrated in FIG. 1, taken along the line B-B in FIGS. 3 and 8.

FIG. 10 is a rear diagram illustrating a structure of a third modified example of the second SDD chip used in the X-ray detector illustrated in FIG. 1.

FIG. 11 is a cross sectional diagram illustrating a third modified example of the laminated structure of the first SDD chip and the second SDD chip used in the X-ray detector illustrated in FIG. 1, taken along the line B-B in FIGS. 3 and 10.

FIG. 12 is a rear diagram illustrating a structure of a fourth modified example of the second SDD chip used in the X-ray detector illustrated in FIG. 1.

FIG. 13 is a cross sectional diagram illustrating a fourth modified example of the laminated structure of the first SDD chip and the second SDD chip used in the X-ray detector illustrated in FIG. 1, taken along the line B-B in FIGS. 3 and 12.

FIG. 14 is a schematic diagram illustrating an example of a configuration of an X-ray measurement device provided with the X-ray detector according to the embodiment of the present invention.

FIG. 15 is a flowchart illustrating an example of a processing procedure in the X-ray measurement device illustrated in FIG. 14.

FIG. 16 is a schematic diagram illustrating the configuration of the X-ray measurement device of a modified example according to the embodiment of the present invention.

FIG. 17 is a data diagram illustrating an effect of the X-ray detector according to the embodiment of the present invention.

FIG. 18 is a data diagram illustrating another effect of the X-ray detector according to the embodiment of the present invention.

### DESCRIPTION OF EMBODIMENTS

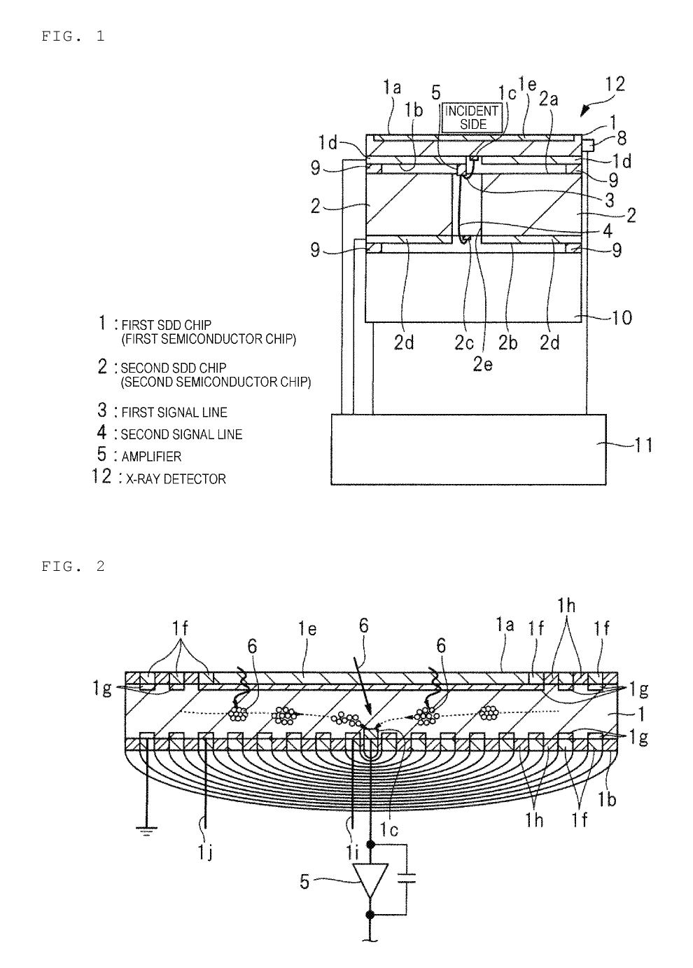

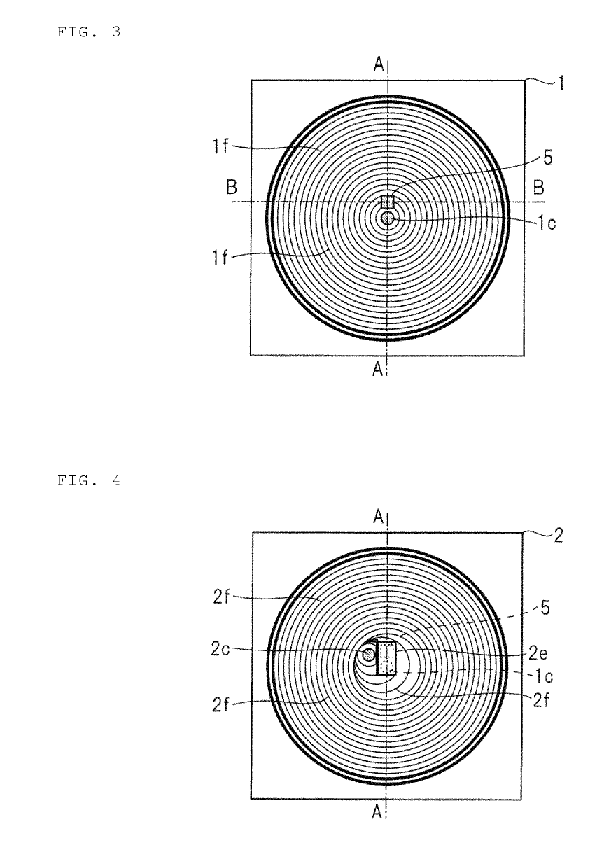

FIG. 1 is a schematic diagram illustrating an example of a configuration of an X-ray detector according to an embodiment of the present invention, and FIG. 2 is a schematic diagram illustrating a broken part of a structure of an SDD chip used in the X-ray detector illustrated in FIG. 1.

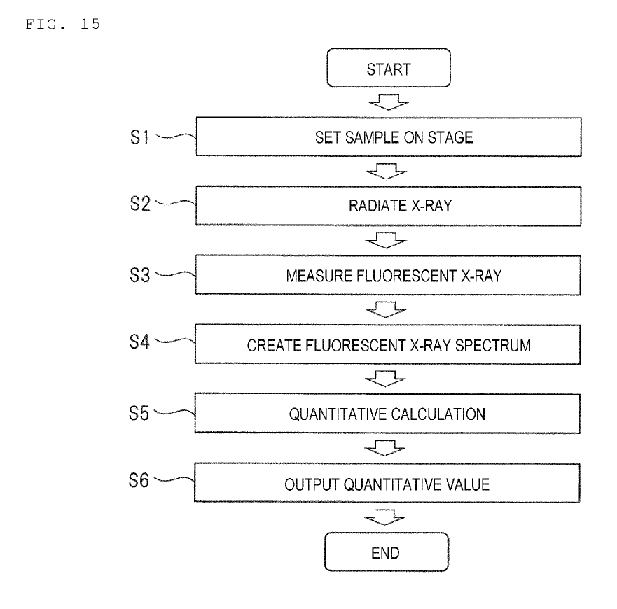

As illustrated in FIG. 14 which will be described later, an X-ray detector 12 in the embodiment illustrated in FIG. 1 is a device capable of performing qualitative and quantitative analysis of a substance by irradiating the substance with an X-ray 6 and detecting a fluorescent X-ray 7 generated therefrom.

To describe a configuration of the X-ray detector 12, the X-ray detector 12 includes a first SDD chip (first semiconductor chip) 1 that irradiates a sample (specimen) 24 illustrated in FIG. 14 with the X-ray 6 and detects the fluorescent X-ray 7 generated from the sample 24 with a first energy sensitivity, and a second SDD chip (second semiconductor chip) 2 that detects the fluorescent X-ray 7 with a second energy sensitivity different from the first energy sensitivity.

The X-ray detector 12 includes a first signal line 3 electrically connected to the first SDD chip 1, a second signal line 4 electrically connected to the second SDD chip 2, and an amplifier 5 that is electrically connected to the first signal line 3 and the second signal line 4 and amplifies a signal.

The X-ray detector 12 includes a Peltier 10 that absorbs heat of each element (each semiconductor chip), and a thermistor 8 which is a temperature sensor that detects a temperature of each element (each semiconductor chip) is mounted thereon.

The X-ray detector 12 is provided with a control part 11 that is electrically connected to each semiconductor chip, the Peltier 10, the thermistor 8, and the like, and controls power supply control, temperature control, signal processing, and the like.

In the X-ray detector 12, the first SDD chip 1 and the second SDD chip 2 are disposed to be laminated, and the first SDD chip 1 is disposed on an incident side of the X-ray 6, whereas the second SDD chip 2 is disposed on a side opposite to the incident side of the X-ray 6. That is, in the X-ray detector 12, the first SDD chip 1 and the second SDD chip 2 are disposed in order from the incident side of the X-ray 6. Accordingly, a surface (window surface) 1a of the first SDD chip 1 faces the incident side of the X-ray 6, and a rear surface (ring surface) 1b of the first SDD chip 1 and a surface 2a of the second SDD chip 2 are facing each other.

An insulating spacer 9 is interposed between the first SDD chip 1 and the second SDD chip 2. In other words, the first SDD chip 1 is laminated on the second SDD chip 2 via the spacer 9.

The second SDD chip 2 disposed on the side opposite to the incident side is provided with a through hole (space part) 2e that is opened on the surface 2a thereof and the rear surface 2b thereof at a center part of a chip plane (surface 2a), and the second signal line 4 electrically connected to the second SDD chip 2 is disposed in the through hole 2e.

A wiring layer 1d that is provided with a circuit for extracting a signal of the first SDD chip 1 outside is formed on the rear surface 1b of the first SDD chip 1, whereby the signal of the first SDD chip 1 is extracted outside via an internal wiring of the wiring layer 1d.

In the same manner, a wiring layer 2d that is provided with a circuit for extracting a signal of the second SDD chip 2 outside is formed on the rear surface 2b of the second SDD chip 2, whereby the signal of the second SDD chip 2 is extracted outside via an internal wiring of the wiring layer 2d. A thin film wiring substrate and the like may be adopted as the wiring layer 1d and the wiring layer 2d.

The amplifier 5, which is electrically connected to both the first signal line 3 and the second signal line 4, is provided on the wiring layer 1d provided on the rear surface 1b of the first SDD chip 1.

Specifically, one end of the first signal line 3 is electrically connected to the first SDD chip 1 via an anode electrode (first charge collection electrode) 1c provided at a center part of the rear surface 1b of the first SDD chip 1, and the other end of the first signal line 3 is electrically connected to the amplifier 5 provided on the wiring layer 1d on a side of the rear surface 1b of the first SDD chip 1.

On the other hand, one end of the second signal line 4 is electrically connected to the second SDD chip 2 via an anode electrode (second charge collection electrode) 2c provided at a center part of the rear surface 2b of the second SDD chip 2, the second signal line 4 is disposed in the through hole 2e, and the other end of the second signal line 4 is electrically connected to the amplifier 5 via the through hole 2e.

Here, in the X-ray detector 12 of the embodiment, a thickness of the second SDD chip 2 disposed on the side opposite to the incident side of the X-ray 6 is thicker than a thickness of the first SDD chip 1 disposed on the incident side. As an example, the thickness of the first SDD chip 1 is about 0.5 mm, and the thickness of the second SDD chip 2 is about 1.0 mm.

Next, referring to FIG. 2, a basic configuration of the SDD chip made of a Si substrate will be described. A structure illustrated in FIG. 2 is same as a structure in which the wiring layer 1d of the first SDD chip 1 illustrated in FIG. 1 is removed.

As illustrated in FIG. 2, a side of the surface (window surface) 1a of the SDD chip is the incident surface of the X-ray 6, and on an uppermost layer in the vicinity of a center part thereof, an oxide film 1e is formed. A plurality of wirings 1f made of aluminum and the like are formed in ring shapes around the oxide film 1e as guard rings. A boron layer 1g is formed at a lower part of each ring-shaped wiring 1d and a lower part of the oxide film 1e. An insulating film 1h is formed between the ring-shaped wirings 1f, respectively.

On the other hand, on an uppermost layer on the side of the rear surface (ring surface) 1b of the SDD chip, the plurality of ring-shaped wirings 1f made of aluminum and the like are formed, and the anode electrode 1c is formed at a center part thereof. The boron layer 1g is formed on an upper part of each ring-shaped wiring 1f in the same manner as that on the side of the surface 1a, and the insulating film 1h is formed between the ring-shaped wirings 1f, respectively. The plurality of ring-shaped wirings 1f are the plurality of ring-shaped wirings 1f formed having a same center at equal intervals.

Phosphorus is injected between the respective boron layers 1g of the Si substrate on the side of the surface 1a and the side of the rear surface 1b. The inside of the Si substrate is a depletion layer.

When a voltage is applied to an inner electrode 1i and an outer electrode 1j with respect to such an SDD chip, since the plurality of ring-shaped wirings 1f are spirally formed having same center at equal intervals on the side of the rear surface 1b, an electric field is formed toward a center of the Si substrate. The X-ray 6 is collected by this electric field. In the SDD chip illustrated in FIG. 2, since the anode electrode 1c as a charge collection electrode is provided at the center part of the rear surface 1b, the X-ray 6 can be collected in the anode electrode 1c, thereby making it possible to detect the X-ray 6 with high accuracy.

The X-ray detector 12 of the embodiment adopts the SDD chip of the structure illustrated in FIG. 2 as the first SDD chip 1 illustrated in FIG. 1; different SDD chips are stacked (laminated) in a vertical direction (thickness direction of the SDD chip); the signal lines connected to the respective SDD chips are connected to one amplifier 5; and the SDD chips are operated by a single circuit.

Accordingly, it is not required to handle a Si substrate having a large thickness, whereby an area and a volume of the detector are not increased, and detection efficiency of the X-ray 6 can be improved while resolution thereof is maintained without requiring a plurality of amplifiers and post-stage circuits.

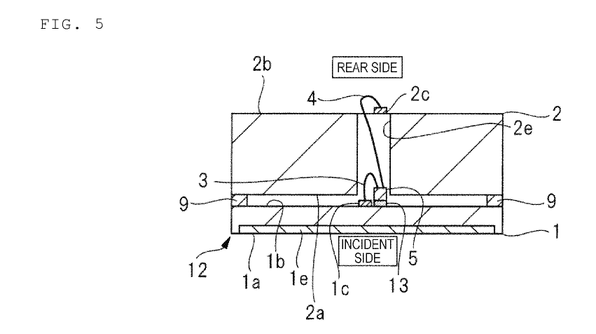

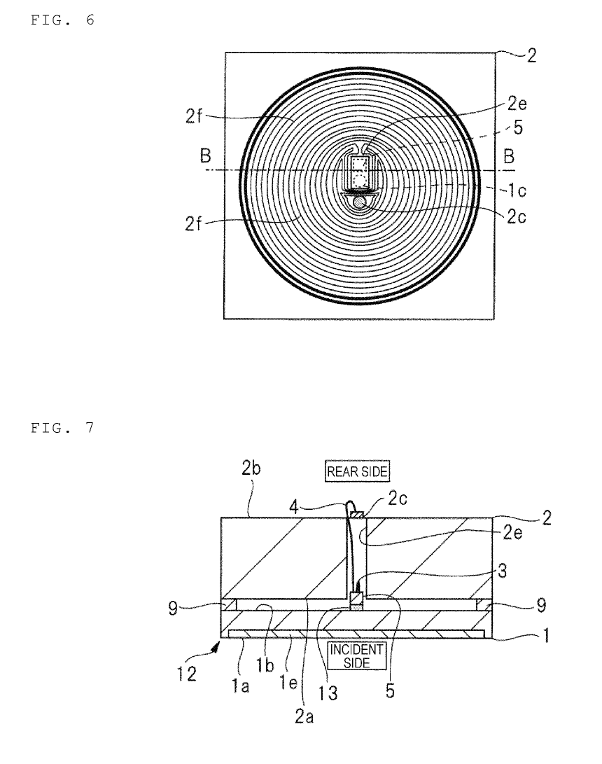

Next, a structure of two SDD chips incorporated in the X-ray detector 12 of the embodiment will be described. FIG. 3 is a rear diagram illustrating an example of a structure of the first SDD chip used in the X-ray detector illustrated in FIG. 1, FIG. 4 is a rear diagram illustrating an example of a structure of the second SDD chip used in the X-ray detector illustrated in FIG. 1, and FIG. 5 is a cross sectional diagram illustrating an example of a laminated structure of the first SDD chip and the second SDD chip used in the X-ray detector illustrated in FIG. 1, taken along the line A-A in FIGS. 3 and 4.

Out of the two SDD chips laminated in the X-ray detector 12 of the embodiment, the SDD chip illustrated in FIG. 3 corresponds to the first SDD chip 1 disposed on the incident side of the X-ray 6, and illustrates the structure of the side of the rear surface 1b of the first SDD chip 1. That is, the first SDD chip 1 illustrated in FIG. 3 has same structure as the SDD chip illustrated in FIG. 2.

Specifically, as illustrated in FIG. 5, the oxide film 1e is formed on the surface 1a of the first SDD chip 1. On the other hand, on the side of the rear surface 1b, as illustrated in FIG. 3, the plurality of ring-shaped wirings 1f made of aluminum and the like are formed having same center at equal intervals. The anode electrode 1c and the amplifier 5 are provided at the center part of the rear surface 1b. As illustrated in FIG. 5, for example, the amplifier 5 is mounted on the rear surface 1b of the first SDD chip 1 via an adhesive material 13.

The SDD chip illustrated in FIG. 4 is the second SDD chip 2 which is disposed on the side opposite to the incident side of the X-ray 6 and laminated with the first SDD chip 1. The through hole (space part) 2e is formed at the center part in a plane direction of the second SDD chip 2. As illustrated in FIG. 5, the through hole 2e is opened on the surface 2a and the rear surface 2b of the second SDD chip 2.

As described above, the X-ray detector 12 of the embodiment is formed by laminating the first SDD chip 1 and the second SDD chip 2, and detects the respective signals by one amplifier 5. That is, the SDD operation is executed by a single circuit. For example, the respective signals detected by the amplifier 5 are extracted outside of the chip via the internal wiring of the wiring layer 1d illustrated in FIG. 1.

In the second SDD chip 2, the space part (gap) such as the through hole 2e is formed to connect the signal line (second signal line 4) to the amplifier 5 provided on the rear surface 1b of the first SDD chip 1. In other words, as illustrated in FIG. 5, in the second SDD chip 2, the second signal line 4 that is electrically connected via the anode electrode 2c on the rear surface 2b passes through the through hole 2e, and the second signal line 4 is drawn out to the side of the surface 2a via the through hole 2e. The second signal line 4 drawn out to the side of the surface 2a is electrically connected to the amplifier 5 mounted on the rear surface 1b of the first SDD chip 1.

As illustrated in FIG. 4, a shape of the through hole 2e in a plan view is a vertically elongated rectangular shape.

The anode electrode (second charge collection electrode) 2c is provided along a long side of the vertically elongated rectangular shape of an opening part of the through hole 2e on the rear surface 2b, and the second signal line 4 is electrically connected to the anode electrode 2c.

On the rear surface 2b of the second SDD chip 2, a plurality of wirings 2f are formed having approximately the same center at equal intervals surrounding the anode electrode 2c and the through hole 2e while the anode electrode 2c and the through hole 2e are disposed at the center part.

Here, in the X-ray detector 12 of the embodiment, since the first SDD chip 1 and the second SDD chip 2 are disposed to be laminated in the incident direction of the X-ray 6, the first energy sensitivity for detecting the fluorescent X-ray 7 of the first SDD chip 1 is different from the second energy sensitivity for detecting the fluorescent X-ray 7 of the second SDD chip 2. That is, the second SDD chip 2 disposed on the rear side regarding the incident direction of the X-ray 6 has the energy sensitivity inevitably different from that of the first SDD chip 1 on the incident side. In other words, the sensitivity of the two SDD chips is different as the two SDD chips are laminated. In this case, the second SDD chip 2 on the rear side has higher energy sensitivity compared with the first SDD chip 1 on the incident side.

Therefore, for example, the X-ray 6 having energy equal to or greater than 10 keV can be detected by the second SDD chip 2 on the rear side, and the X-ray 6 having energy not exceeding 10 keV can be detected by the first SDD chip 1 on the incident side.

The thickness of the second SDD chip 2 in the X-ray detector 12 of the embodiment is thicker than that of the first SDD chip 1. For example, the thickness of the first SDD chip 1 is about 0.5 mm, and the thickness of the second SDD chip 2 is about 1.0 mm. However, the thickness of the first SDD chip 1 and the thickness of the second SDD chip 2 may be same.

In the X-ray detector 12 of the embodiment, the first SDD chip 1 and the second SDD chip 2 are laminated, and the signal line of the second SDD chip 2 passes through the space part provided in the second SDD chip 2, thereby making it possible to detect the respective signals of both SDD chips by one amplifier 5. As a result, since there is no need to increase an occupancy area and a volume of the X-ray detector 12, miniaturization of the X-ray detector 12 can be achieved.

When attempting to detect the X-ray 6 having energy equal to or greater than 10 keV, in the Si substrate, there exists a characteristic that the sensitivity of the X-ray 6 dramatically deteriorates. As a countermeasure for increasing the detection sensitivity of the X-ray 6 having high energy, simply increasing the thickness of the Si substrate maybe considered. However, when the Si substrate is thickened, some problems occur such as the followings. (1) When the SDD chip is manufactured, it becomes difficult to handle and convey the Si substrate. (2) A leakage current affecting the resolution of the SDD chip increases. (3) An effective area of the window surface (window region) on which the X-ray 6 is incident becomes small in inverse proportion to the thickness of the Si substrate.

Here, the X-ray detector 12 of the embodiment does not simply thicken the thickness of the SDD chip, but laminates the first SDD chip 1 and the second SDD chip 2 which are two SDD chips. Accordingly, occurrence of the above-mentioned problems from (1) to (3) when simply thickening the thickness of the SDD chip can be avoided.

In the X-ray detector 12, since the energy sensitivity of each of the two SDD chips is different from each other by laminating the first SDD chip 1 and the second SDD chip 2, as a result, the detection efficiency of the X-ray 6 can be improved while maintaining the high resolution in the X-ray detection. It is possible to increase the detection efficiency of the X-ray 6 by preventing an increase in cost.

In the X-ray detector 12 of the embodiment, the thickness of the second SDD chip 2 on the rear side is thicker than the thickness of the first SDD chip 1 on the incident side. Thus, the second SDD chip 2 on the rear side can be used exclusively for the detection of the X-ray having the high energy. In this case, by setting the thickness of the second SDD chip 2 to, for example, about 1.0 mm, the occurrence of the problems when thickening the Si substrate can be avoided.

Next, modified examples of the X-ray detector 12 of the embodiment will be described.

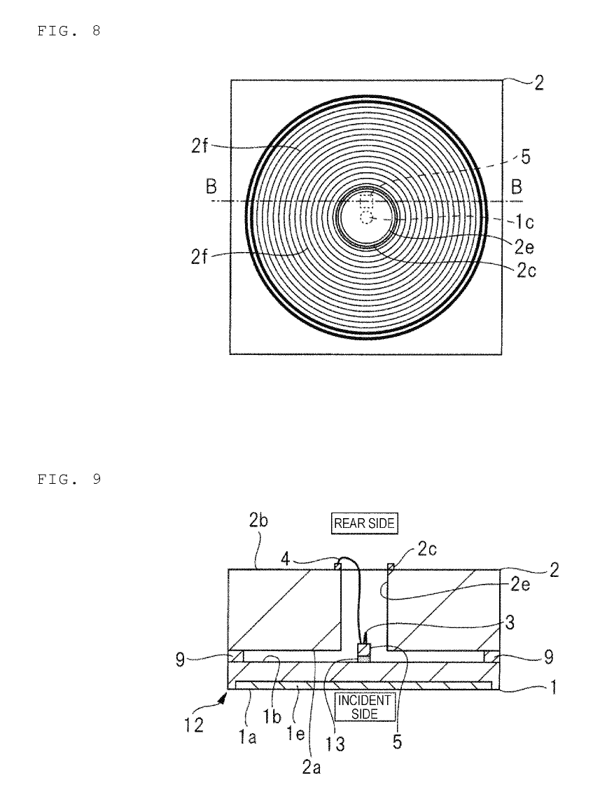

FIG. 6 is a rear diagram illustrating a structure of a first modified example of the second SDD chip used in the X-ray detector illustrated in FIG. 1, and FIG. 7 is a cross sectional diagram illustrating a first modified example of the laminated structure of the first SDD chip and the second SDD chip used in the X-ray detector illustrated in FIG. 1, taken along the line B-B in FIGS. 3 and 6.

Since a structure of the first SDD chip 1 in the X-ray detector 12 of the first modified example illustrated in FIG. 7 is same as the structure of the first SDD chip 1 illustrated in FIG. 3, redundant descriptions thereof will be omitted.

In the second SDD chip 2 illustrated in FIG. 6, the through hole (space part) 2e forming a vertically elongated rectangular shape in a plan view is formed at the center part in the plane direction thereof. The anode electrode (second charge collection electrode) 2c is provided along a short side of the vertically elongated rectangular shape of the opening part of the through hole 2e on the rear surface 2b. As illustrated in FIG. 7, the second signal line 4 is electrically connected to the anode electrode 2c.

On the rear surface 2b of the second SDD chip 2, the plurality of wirings 2f are formed having approximately the same center at equal intervals surrounding the anode electrode 2c and the through hole 2e while the anode electrode 2c and the through hole 2e are disposed at the center part.

In the X-ray detector 12 illustrated in FIG. 7, the plurality of ring-shaped wirings 2f are formed in a spiral pattern approximately equally even around the anode electrode 2c on the side of the rear surface 2b of the second SDD chip 2 as illustrated in FIG. 6. That is, in the second SDD chip 2 illustrated in FIG. 6 compared with the second SDD chip 2 illustrated in FIG. 4, since the electric field is also formed around the anode electrode 2c, it is possible to further expand a region where the X-ray 6 can be detected.

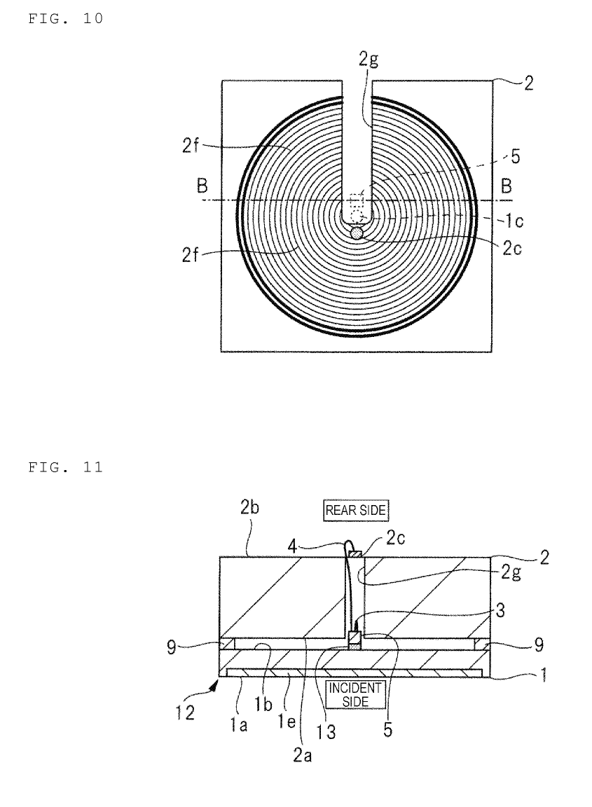

FIG. 8 is a rear diagram illustrating a structure of a second modified example of the second SDD chip used in the X-ray detector illustrated in FIG. 1, and FIG. 9 is a cross sectional diagram illustrating a second modified example of the laminated structure of the first SDD chip and the second SDD chip used in the X-ray detector illustrated in FIG. 1, taken along the line B-B in FIGS. 3 and 8.

Since the structure of the first SDD chip 1 in the X-ray detector 12 of the second modified example illustrated in FIG. 9 is same as the structure of the first SDD chip 1 illustrated in FIG. 3, redundant descriptions thereof will be omitted.

As illustrated in FIG. 8, in the second SDD chip 2, the through hole (space part) 2e circular in a plan view is formed at the center part in the plane direction thereof. That is, the through hole 2e having a cylindrical shape is formed at the center part of the rear surface 2b of the second SDD chip 2. The circular anode electrode (second charge collection electrode) 2c is formed along the circular opening part of the through hole 2e on the rear surface 2b.

As illustrated in FIG. 9, on the rear surface 2b of the second SDD chip 2, the plurality of ring-shaped wirings 2f illustrated in FIG. 8 are formed having same center at equal intervals surrounding the anode electrode 2c and the through hole 2e while the anode electrode 2c and the through hole 2e are disposed at the center part.

Therefore, the circular opening part of the through hole 2e, the circular anode electrode 2c formed along the opening part, and the plurality of ring-shaped wirings 2f are formed having same center.

As illustrated in FIG. 9, the second signal line 4 is electrically connected to the anode electrode 2c, and the second signal line 4 is electrically connected to the amplifier 5 mounted on the first SDD chip 1 through the through hole 2e.

In the X-ray detector 12 illustrated in FIG. 9, the plurality of wirings 2f illustrated in FIG. 8 are the only wirings 2f having a ring shape formed having same center, whereby shapes of electric fields formed by these wirings 2f are easy to understand. Thus, a design of the X-ray detector 12 can be easily performed. Since the through hole 2e formed in the second SDD chip 2 also has a cylindrical shape, the through hole 2e can be easily formed.

FIG. 10 is a rear diagram illustrating a structure of a third modified example of the second SDD chip used in the X-ray detector illustrated in FIG. 1, and FIG. 11 is a cross sectional diagram illustrating a third modified example of the laminated structure of the first SDD chip and the second SDD chip used in the X-ray detector illustrated in FIG. 1, taken along the line B-B in FIGS. 3 and 10.

Since the structure of the first SDD chip 1 in the X-ray detector 12 of the third modified example illustrated in FIG. 11 is same as the structure of the first SDD chip 1 illustrated in FIG. 3, redundant descriptions thereof will be omitted.

The second SDD chip 2 illustrated in FIG. 10 is formed with a notch (space part) 2g extending from an end part to a center part in a plan view. As illustrated in FIG. 11, the notch 2g is opened on the surface 2a and the rear surface 2b of the second SDD chip 2, and is also opened on the side surface of the second SDD chip 2 as illustrated in FIG. 10.

On the rear surface 2b illustrated in FIG. 10, the anode electrode (second charge collection electrode) 2c is formed along a terminal end part of the notch 2g at the center part thereof.

The plurality of ring-shaped wirings 2f are formed having same center at equal intervals on the rear surface 2b of the second SDD chip 2.

As illustrated in FIG. 11, the second signal line 4 is electrically connected to the anode electrode 2c, and the second signal line 4 is electrically connected to the amplifier 5 mounted on the first SDD chip 1 through the notch 2g.

In the X-ray detector 12 illustrated in FIG. 11, the notch 2g as the space part can be formed in the second SDD chip 2 by dicing and laser processing during chip individualization. Accordingly, a manufacturing process of the chip is facilitated compared with a process of forming the space part such as the through hole 2e at a wafer level, thereby making it possible to reduce the manufacturing cost of the second SDD chip 2.

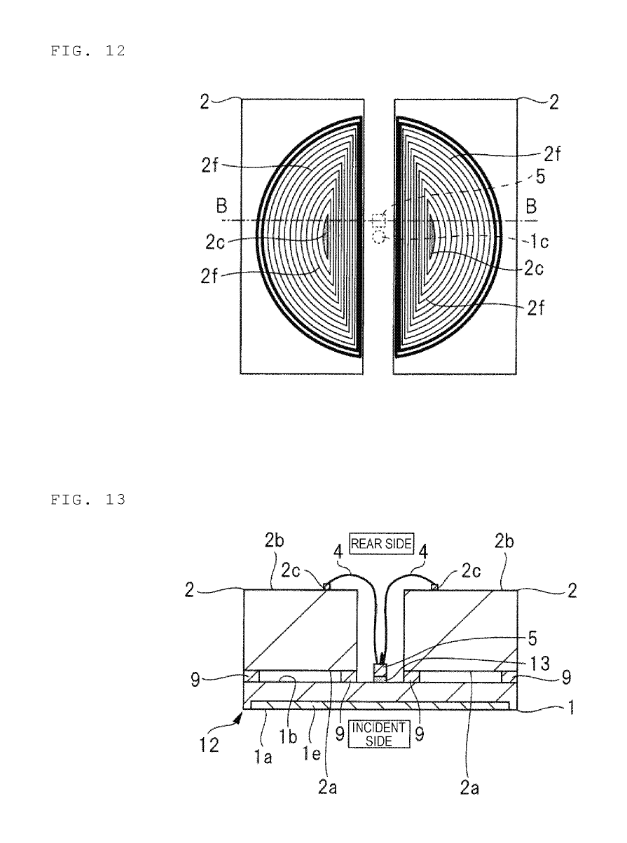

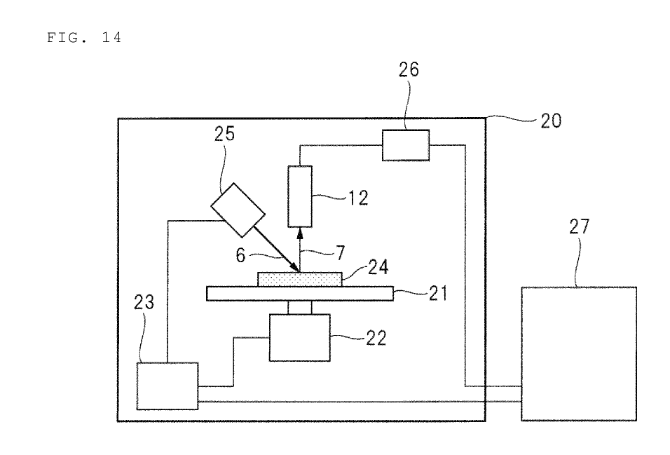

FIG. 12 is a rear diagram illustrating a structure of a fourth modified example of the second SDD chip used in the X-ray detector illustrated in FIG. 1, and FIG. 13 is a cross sectional diagram illustrating a fourth modified example of the laminated structure of the first SDD chip and the second SDD chip used in the X-ray detector illustrated in FIG. 1, taken along the line B-B in FIGS. 3 and 12.

Since the structure of the first SDD chip 1 in the X-ray detector 12 of the fourth modified example illustrated in FIG. 13 is same as the structure of the first SDD chip 1 illustrated in FIG. 3, redundant descriptions thereof will be omitted.

As illustrated in FIGS. 12 and 13, the fourth modified example is the X-ray detector 12 having a structure in which the two second SDD chips 2 are laminated side by side on the first SDD chip 1. That is, the X-ray detector 12 uses three SDD chips.

The X-ray detector 12 illustrated in FIG. 13 has a structure in which the two second SDD chips 2 are disposed on the first SDD chip 1, and a space part is formed between the two second SDD chips 2, whereby the respective signal lines of the two second SDD chips 2 are disposed in the space part and are electrically connected to the amplifier 5 mounted on the rear surface 1b of the first SDD chip 1.

That is, the X-ray detector 12 has a structure in which the anode electrode 2c is formed on the respective rear surfaces 2b of the two second SDD chips 2, the two second signal lines 4 connected to the respective anode electrodes 2c pass through the space part between the two second SDD chips 2, and each of the two second signal lines 4 is electrically connected to the amplifier 5 mounted on the rear surface 1b of the first SDD chip 1.

In the X-ray detector 12 illustrated in FIG. 13, any processing for forming the space part in either the first SDD chip 1 or the two second SDD chips 2 is unnecessary. As a result, each SDD chip can be easily manufactured. The manufacturing cost of each SDD chip can be reduced.

Next, an X-ray measurement device according to the embodiment will be described.

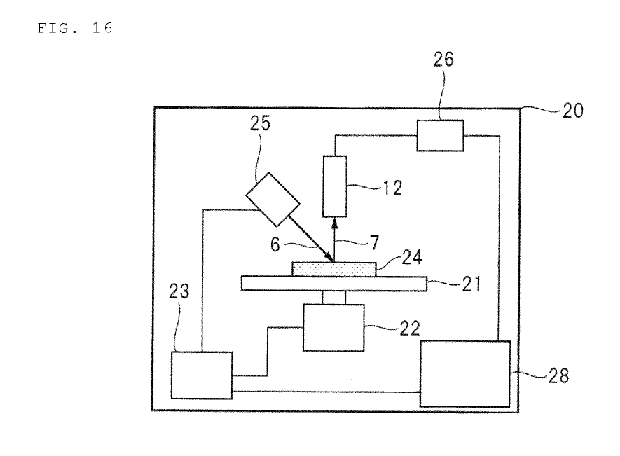

FIG. 14 is a schematic diagram illustrating an example of a configuration of an X-ray measurement device provided with the X-ray detector according to the embodiment of the present invention, and FIG. 15 is a flowchart illustrating an example of a processing procedure in the X-ray measurement device illustrated in FIG. 14.

An X-ray measurement device 20 of the embodiment illustrated in FIG. 14 is provided with the X-ray detector 12 of the embodiment, and performs quantitative value processing and the like of an element (substance) of the X-ray 6 detected by the X-ray detector 12. For example, it is possible not only to calculate a film thickness and the like of the substance detected by the X-ray detector 12, but also to be utilized as a film thickness measurement device.

When a configuration of the X-ray measurement device 20 illustrated in FIG. 14 is described, the X-ray measurement device 20 includes a stage 21 that holds a sample (specimen) 24, an X-ray generation source 25 that irradiates the sample 24 with the X-ray 6, the X-ray detector 12 that detects the fluorescent X-ray 7 generated from the sample 24, and a first processing part that edits a signal transmitted from the X-ray detector 12.

Here, in the X-ray measurement device 20 illustrated in FIG. 14, the first processing part is a digital pulse processor (DPP) 26, and the DPP 26 is a device that edits a digital signal (pulse or waveform) transmitted from the X-ray detector 12 and transmits the edited digital signal to a control personal computer (PC, second processing part) 27.

The X-ray detector 12 is same as the X-ray detector 12 illustrated in FIG. 1 and the X-ray detector 12 illustrated in FIGS. 3 to 11. That is, the configuration of the X-ray detector 12 includes the first SDD chip (first semiconductor chip) 1 that detects the fluorescent X-ray 7 with the first energy sensitivity, and the second SDD chip (second semiconductor chip) 2 that detects the fluorescent X-ray 7 with the second energy sensitivity different from the first energy sensitivity. The X-ray detector 12 includes the first signal line 3 electrically connected to the first SDD chip 1, the second signal line 4 electrically connected to the second SDD chip 2, and the amplifier 5 which is electrically connected to the first signal line 3 and the second signal line 4 and amplifies the signal.

The X-ray measurement device 20 includes a driving driver 22 that drives the stage 21 and is provided with a power source 23 that supplies a power source to the driving driver 22 and the X-ray generation source 25.

The control PC (second processing part) 27 is connected to the X-ray measurement device 20 as described above. As illustrated in FIG. 14, in the X-ray measurement device 20 of the embodiment, the control PC 27 is connected to outside thereof, information on the element (substance) of the X-ray 6 edited by the DPP 26 is transmitted to the control PC 27, and the quantitative value processing and the like of the element (substance) are performed by the control PC 27 provided outside the X-ray measurement device 20.

Next, general operations of the X-ray measurement device 20 illustrated in FIG. 14 will be described with reference to FIG. 15. First, “set sample on stage” indicated at step S1 of FIG. 15 is performed. At step S1, the sample (specimen) 24 is set on the stage 21.

Next, “irradiate X-ray” indicated at step S2 is performed. At step S2, the stage 21 is first moved to a predetermined position by the driving driver 22. Thereafter, a predetermined portion of the sample 24 is irradiated with the X-ray 6 from the X-ray generation source 25.

Next, “measure fluorescent X-ray” indicated at step S3 is performed. At step S3, the fluorescent X-ray 7 generated from the sample 24 is detected by the X-ray detector 12. In the X-ray detector 12, when the fluorescent X-ray 7 is incident, a pair of “e” and “Hole” depending on the energy of the X-ray 6 is internally generated, the amplifier 5 amplifies a current value corresponding to the number of the generation and converts the amplified current value into a voltage, and the converted voltage is output as a pulse signal (waveform).

Next, “create fluorescent X-ray spectrum” indicated at step S4 is performed. At step S4, the pulse signal transmitted from the X-ray detector 12 is edited by the DPP 26, thereby creating a fluorescent X-ray spectrum (fluorescent X-ray intensity).

Next, “quantitative calculation” indicated at step S5 is performed. At step S5, in the control PC 27, analysis (calculation) is performed by a dedicated program incorporated therein, based upon a numerical value transmitted from the DPP 26.

Next, “output quantitative value” indicated at step S6 is performed. At step S6, the quantitative value processing of the detected element is performed by the control PC 27, and the quantitative value of the detected element is output.

According to the X-ray measurement device 20 of the embodiment, since the X-ray detector 12 of the embodiment is incorporated inside thereof, the detection efficiency of the X-ray can be improved while maintaining high resolution. Since the miniaturization of the X-ray detector 12 incorporated inside thereof can be achieved, the miniaturization of the X-ray measurement device 20 can also be achieved.

Since the X-ray detector 12 is incorporated therein, the detection efficiency of the X-ray 6 can be improved while preventing the increase in cost of the X-ray measurement device 20.

Next, a modified example of the X-ray measurement device 20 of the embodiment will be described. FIG. 16 is a schematic diagram illustrating the configuration of the X-ray measurement device of a modified example according to the embodiment of the present invention.

The X-ray measurement device 20 of the modified example illustrated in FIG. 16 includes therein a control part (second processing part) 28 that calculates a quantitative value of an element of the fluorescent X-ray 7 detected by the X-ray detector 12 based upon information transmitted from the DPP (first processing part) 26.

That is, in the X-ray measurement device 20 illustrated in FIG. 14, the control PC 27 that calculates the quantitative value of the element of the fluorescent X-ray 7 is provided outside the X-ray measurement device 20, and the control PC 27 and the X-ray measurement device 20 are connected to each other. On the other hand, in the X-ray measurement device 20 of the modified example illustrated in FIG. 16, the control part 28 that calculates the quantitative value of the element of the fluorescent X-ray 7 is provided in the X-ray measurement device 20. That is, the X-ray measurement device 20 of the modified example illustrated in FIG. 16 incorporates the control part 28 that calculates the quantitative value of the element of the fluorescent X-ray 7.

Accordingly, a function of the X-ray measurement device 20 can be improved. The detection efficiency of the X-ray 6 can be improved while preventing the increase in cost of the X-ray measurement device 20.

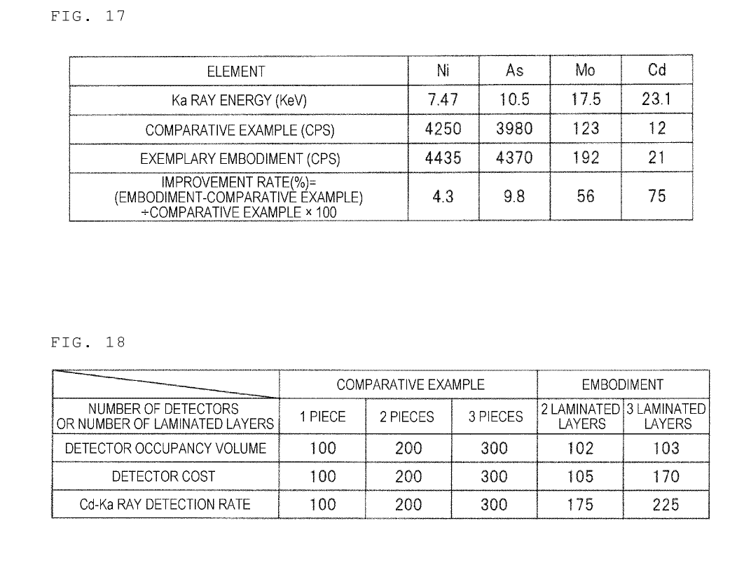

Next, referring to FIGS. 17 and 18, simulation of effects performed by the present inventor will be described. FIG. 17 is a data diagram illustrating an effect achieved by the X-ray detector according to the embodiment of the present invention; and FIG. 18 is a data diagram illustrating another effect achieved by the X-ray detector according to the embodiment of the present invention.

FIG. 17 illustrates a comparison between a comparative example and the embodiment with respect to Ka ray energy of each element and X-ray count (CPS) thereof. An improvement rate in FIG. 17 increases as the Ka ray energy increases. The reason why the improvement rate of Ni and As is low is that since the Ka ray energy is lower than or close to 10 KeV, most of the Ka rays are detected by a first detector (first SDD chip 1), and the effect of laminating the two SDDs is considered to be small.

On the other hand, as the Ka ray energy becomes greater than 10 KeV, the improvement rate becomes higher. The reason is that as the Ka ray energy becomes higher, it is easy to pass through the first detector (first SDD chip 1), and a ratio of being detected by a second detector (second SDD chip 2) is increased. Accordingly, the effect of the way of laminating the two SDD chips according to the embodiment is high, and as the X-ray becomes the higher energy, the effect becomes greater. From the above-mentioned result, it can be estimated that increasing the number of laminated SDD chips from two pieces to three pieces further increases the improvement rate.

FIG. 18 illustrates a comparison with the embodiment while a detector occupancy volume, a detector cost, and a Cd-Ka ray detection rate according to the comparative example are defined as 100. In the comparative example, as the number of detectors increases, the detector occupancy volume, the detector cost, and the Cd-Ka ray detection rate increase proportionally. To double the Cd-Ka ray detection rate, the detection occupancy volume and the detector cost also become doubled. On the other hand, when the SDD chips are laminated in two layers as in the embodiment, the Cd-Ka ray detection rate can be 1.75 times with almost no change in the detector occupancy volume and the detector cost. To make the Cd-Ka ray detection rate twice or more, it is required to laminate three SDD chips of the embodiment, but the detector cost becomes high.

When the X-ray detector 12 having high efficiency and high energy of the embodiment is applied to compositional analysis of environmental load substances regulated by the RoHS directive, it is possible to improve fluorescent X-ray intensity higher than 10 KeV compared with the comparative example. For example, Ka ray (23.1 KeV) intensity of Cd contained in Pb free solder can be 1.7 times, Kb ray (26.2 KeV) intensity can be 1.8 times, and Lb1 ray (12.6 KeV) intensity of Pb can be 1.2 times.

When detecting polybrominated biphenyl (PBB) contained in the printed substrate as Br, the Ka ray (11.9 KeV) intensity of Br can be 1.2 times and the Kb ray (13.3 KeV) intensity can be 1.3 times. Particularly, since a regulated value of Cd is ten times more strict than those of other substances (<100 ppm), the way of the embodiment has a great effect of improving the analysis accuracy of Cd.

As described above, the present invention is not limited to the above-mentioned embodiments, but includes various modifications. For example, the above-mentioned embodiments are described in detail to describe the present invention in an easy-to-understand manner, and are not necessarily limited to those including all of the configurations described herein.

A part of the configuration of one embodiment can be replaced with a configuration of another embodiment, and the configuration of another embodiment can be added to the configuration of one embodiment. It is possible to add, delete, and replace another configuration regarding a part of the configuration of each embodiment. Each member and relative size described in the drawings are simplified and idealized to describe the present invention in an easy-to-understand manner, and a more complicated shape is achieved during the implementation.

For example, in the above-mentioned embodiments, two SDD chips laminated are described, but three or more SDD chips may be laminated.

In the above-mentioned embodiments, to laminate two SDD chips, two SDD chips having different thicknesses laminated are described, but two SDD chips having same thickness may be laminated, and two completely same SDD chips may be laminated.

### REFERENCE SIGNS LIST

1: first SDD chip (first semiconductor chip)

1a: surface

1b: rear surface

1c: anode electrode (first charge collection electrode)

1d: wiring layer

1e: oxide film

1f: wiring

1g: boron layer

1h: insulating film

1i: inner electrode

1j: outer electrode

2: second SDD chip (second semiconductor chip)

2a: surface

2b: rear surface

2c: anode electrode (second charge collection electrode)

2d: wiring layer

2e: through hole (space part)

2f: wiring

2g: notch (space part)

3: first signal line

4: second signal line

5: amplifier

6: X-ray

7: fluorescent X-ray

8: thermistor

9: spacer

10: Peltier

11: control part

12: X-ray detector

13: adhesive material

20: X-ray measurement device

21: stage

22: driving driver

23: power source

24: sample (specimen)

25: X-ray generation source

26: DPP (first processing part)

27: control PC (second processing part)

28: control part (second processing part)

1. An X-ray detector, comprising:
a first semiconductor chip to detect an X-ray generated from a sample with a first energy sensitivity;
a second semiconductor chip to detect the X-ray with a second energy sensitivity different from the first energy sensitivity;
a first signal line electrically connected to the first semiconductor chip;
a second signal line electrically connected to the second semiconductor chip; and
an amplifier that is electrically connected to the first signal line and the second signal line and amplifies a signal.

2. The X-ray detector according to claim 1, wherein
the first semiconductor chip and the second semiconductor chip are disposed to be laminated.

3. The X-ray detector according to claim 2, wherein
the first semiconductor chip is disposed on an incident side of the X-ray, and
a thickness of the second semiconductor chip is thicker than a thickness of the first semiconductor chip.

4. The X-ray detector according to claim 1, wherein
the second semiconductor chip is provided with a space part that is opened on a surface of the second semiconductor chip and a rear surface thereof, and
the second signal line is disposed in the space part.

5. The X-ray detector according to claim 4, wherein
one end of the first signal line is electrically connected to the first semiconductor chip via a first charge collection electrode provided at a center part of the rear surface of the first semiconductor chip, and the other end of the first signal line is electrically connected to the amplifier provided on the rear surface of the first semiconductor chip, and
one end of the second signal line is electrically connected to the second semiconductor chip via a second charge collection electrode provided at a center part of the rear surface of the second semiconductor chip, and the other end of the second signal line is electrically connected to the amplifier through the space part.

6. The X-ray detector according to claim 5, wherein
the second semiconductor chip is provided with a cylindrical through hole opened on the surface of the second semiconductor chip and the rear surface thereof at a center part in a plane direction, and
the second charge collection electrode is formed in a circular shape along an opening part of the through hole on the rear surface of the second semiconductor chip.

7. An X-ray measurement device, comprising:
a stage to hold a sample;
an X-ray generation source to radiate an X-ray on the sample;
an X-ray detector to detect an X-ray generated from the sample; and
a first processing part to edit a signal transmitted from the X-ray detector, wherein
the X-ray detector includes
a first semiconductor chip to detect the X-ray generated from the sample with a first energy sensitivity,
a second semiconductor chip to detect the X-ray generated from the sample with a second energy sensitivity different from the first energy sensitivity,
a first signal line electrically connected to the first semiconductor chip,
a second signal line electrically connected to the second semiconductor chip, and
an amplifier that is electrically connected to the first signal line and the second signal line and amplifies a signal.

8. The X-ray measurement device according to claim 7, wherein
the first semiconductor chip of the X-ray detector and the second semiconductor chip thereof are disposed to be laminated.

9. The X-ray measurement device according to claim 8, wherein
the first semiconductor chip is disposed on an incident side of the X-ray generated from the sample, and
a thickness of the second semiconductor chip is thicker than a thickness of the first semiconductor chip.

10. The X-ray measurement device according to claim 7, wherein
the second semiconductor chip is provided with a space part that is opened on a surface of the second semiconductor chip and a rear surface thereof, and
the second signal line is disposed in the space part.

11. The X-ray measurement device according to claim 10, wherein
one end of the first signal line is electrically connected to the first semiconductor chip via a first charge collection electrode provided at a center part of the rear surface of the first semiconductor chip, and the other end of the first signal line is electrically connected to the amplifier provided on the rear surface of the first semiconductor chip, and
one end of the second signal line is electrically connected to the second semiconductor chip via a second charge collection electrode provided at a center part of the rear surface of the second semiconductor chip, and the other end of the second signal line is electrically connected to the amplifier through the space part.

12. The X-ray measurement device according to claim 11, wherein
the second semiconductor chip is provided with a cylindrical through hole opened on the surface of the second semiconductor chip and the rear surface thereof at a center part in a plane direction, and
the second charge collection electrode is formed in a circular shape along an opening part of the through hole on the rear surface of the second semiconductor chip.

13. The X-ray measurement device according to claim 7, further comprising:
a second processing part to calculate a quantitative value of an element of the X-ray generated from the sample and detected by the X-ray detector based upon information transmitted from the first processing part.
